(19) United States
(12) Patent Application Publication
(10) Pub. No.: US 2023/0039802 A1
(43) Pub. Date: Feb. 9, 2023

(54) THERMAL MANAGEMENT SYSTEM FOR ANTENNA HOUSING

(71) Applicant: COMPTEK TECHNOLOGIES, LLC, Boulder, CO (US)

(72) Inventors: Dana A. Castronova, Wheat Ridge, CO (US); Kenneth M. Hoganson, Aurora, CO (US)

(21) Appl. No.: 17/749,816

(22) Filed: May 20, 2022

Related U.S. Application Data
(60) Provisional application No. 63/192,478, filed on May 24, 2021.

(51) Int. Cl. H01Q 1/42; H01Q 1/02; H05K 5/02; H05K 7/20

(52) U.S. Cl. CPC H01Q 1/42; H01Q 1/02; H05K 5/0213; H05K 7/20145

(57) ABSTRACT

An antenna housing configured to house a wireless antenna unit. The antenna housing defines an interior space sized to receive a plurality of wireless radios and/or transceivers. Inlet and outlet ducting extends through the interior of the housing from an inlet manifold to an outlet manifold to individually cool each radio. In an arrangement, the inlet manifold draws air from outside the housing and the outlet manifold exhausts air outside of the manifold.

### CROSS REFERENCE

The present application claims the benefit of the filing date of U.S. Provisional Application No. 63/192,478 having a filing date of May 24, 2022, the entire contents of which is incorporated herein by reference.

### FIELD

The present disclosure is broadly directed to antenna housings utilized with wireless access points that provide coverage for local service areas. More specifically, the present disclosure is directed to antenna housings having features to improve thermal management within the housing.

### BACKGROUND

In wireless communication networks, high-powered base stations (e.g., towers supporting antennas) commonly provide service over large geographic areas. Each base station is capable of serving wireless user devices in a coverage area that is primarily determined by signal transmission power of supported antennas. Frequently, high-powered base stations (e.g., macro stations) are located in a grid pattern with each base station mounting various antennas elevated on a tower. While such towers have previously provided adequate coverage for wireless applications, such high-powered base stations tend to be too widely spaced for newer high-bandwidth wireless applications.

To improve wireless access, providers are moving toward smaller stations that provide enhanced coverage for more limited geographic areas. That is, to augment the coverage of the wireless network, wireless transceiver devices/antennas (e.g., access points) with small coverage areas (and serving capacities) are deployed. Depending on their coverage area and serving capacities, these wireless transceiver devices are referred to as “femto” cells or “pico” cells. For simplicity and generality, the terms “small cell pole” or “access point” are used herein to refer to a wireless transceiver unit (e.g., one or more antennas) that is configured to serve wireless user devices over relatively small coverage areas as compared to a high-powered base station that is configured to serve a relatively large coverage area (“macro cell”).

The increasing use of RF bandwidth or ‘mobile data’ has required a corresponding increase in the number of access points to manage the increased data. By way of example, 5G wireless networks providing improved network speeds are currently being implemented. Such networks typically require shorter RF transmission distances compared to existing networks and thereby require more dense networks of access points. Along these lines, local access points are being installed in urban areas to serve several city blocks or even to serve a single city block. Such installations are often below roof-top level of surrounding buildings. That is, access points are being installed at ‘streel-level’ sites typically on small dedicated small cell poles as well as on existing utility poles (e.g., streetlights, stoplights, etc.) and building walls. The increasing number of access points is sometimes referred to as densification of wireless infrastructure. Residents often object to such densification in their neighborhoods due to the aesthetic concerns of wireless antennas supported by various dedicated and/or existing utility poles. To help alleviate aesthetic concerns, wireless provider commonly conceal antennas/radios supported by such poles within a shrouding or antenna housing. Antenna housings having a minimal form factor necessary to house an antenna are typically preferred to minimize to overall obtrusiveness of a set of supported antennas/radios.

### BRIEF DESCRIPTION OF THE DRAWINGS

FIG. 1 illustrates one embodiment of a wireless access point.

FIG. 2A illustrate one embodiment of an antenna assembly.

FIG. 2B illustrates an exploded view of the antenna assembly of FIG. 2A.

FIG. 3A illustrates one embodiment of an antenna housing.

FIG. 3B illustrates the antenna housing of FIG. 3A with an outer shrouding/sidewall removed, in an embodiment.

FIGS. 3C-3E illustrate the antenna housing of FIG. 3A with the shrouding, internal radios and internal ducting removed, in an embodiment.

FIG. 3F illustrates an alternate embodiment of an internal structure of the antenna housing.

FIGS. 4A and 4B illustrate perspective and side views, respectively, of a lower manifold, in an embodiment.

FIGS. 5A and 5B illustrate perspective and side views, respectively, of an upper manifold, in an embodiment.

FIG. 6 illustrates attachment of ducts to an antenna/radio, in an embodiment.

FIG. 7 illustrates connection of two antennas/radios in a fluid path between a lower manifold and an upper manifold, in an embodiment.

FIG. 8 illustrates a three-dimensional air deflector, in an embodiment.

FIG. 9 illustrates air flow through an interior of an antenna housing, in an embodiment.

FIG. 10 illustrates an end plate of an antenna housing, in an embodiment.

### DETAILED DESCRIPTION

Reference will now be made to the accompanying drawings, which at least assist in illustrating the various pertinent features of the presented inventions. The following description is presented for purposes of illustration and description and is not intended to limit the inventions to the forms disclosed herein. Consequently, variations and modifications commensurate with the following teachings, and skill and knowledge of the relevant art, are within the scope of the presented inventions. The embodiments described herein are further intended to explain the best modes known of practicing the inventions and to enable others skilled in the art to utilize the inventions in such, or other embodiments and with various modifications required by the particular application(s) or use(s) of the presented inventions.

Aspects of the present disclosure are based on the realization that the use of ever increasingly powerful antennas/radios to enhance coverage and/or data transfer, in conjunction with efforts to minimize the size (e.g., form factor) of antenna housings to address aesthetic concerns, can result in thermal management concerns for a wireless access point. These concerns are of particular importance for access points incorporating a plurality of antennas. When such a plurality of antennas/radios are enclosed within a housing or shrouding, heat generated by operation of the radios is at least partially contained within the housing. This can result in the radios operating in a thermal environment above recommended operation temperatures. Accordingly, the present disclosure is directed to an antenna housing assembly and/or shrouding assembly that allows for, among other things, individually venting radios to reduce the temperature within an interior of the antenna housing as well as incorporating additional features to remove heat from an interior of the antenna housing.

In one implementation, an antenna housing is provided. The antenna housing is primarily configured to be mounted to a pole (dedicated or existing), though this is not a strict requirement. The antenna housing may be a modular housing configured to mount to and/or support another antenna housing (e.g., similarly, or differently configured). Wireless antennas/radios supported by the housing are at least partially disposed within the interior of the antenna housing such that they are partially concealed. That is, the antennas/radios are at least partially enclosed within a sidewall and/or shrouding of the housing and an active or emitting surface of the antenna(s) is typically directed outward from the interior of the housing. In some arrangements, an emitting surface may be exposed through an aperture in the sidewall and/or shrouding.

The present disclosure is broadly directed to wireless antenna housings (e.g., antenna or radio support assemblies) that are intended for use with small cell poles and/or access points primarily in urban environments. In various embodiments, the antenna housings at least partially conceal supported wireless transceivers (e.g., radios or antennas) within an enclosed interior of the housing to minimize their aesthetic obtrusiveness. Various embodiments of the present disclosure are directed to an antenna housing and/or shrouding assembly that provides individual venting of radios as well as physical features within the housing to facilitate movement of air through the interior of the housing for cooling. Such features may work alone and/or in conjunction to reduce the temperature within an interior of the antenna housing.

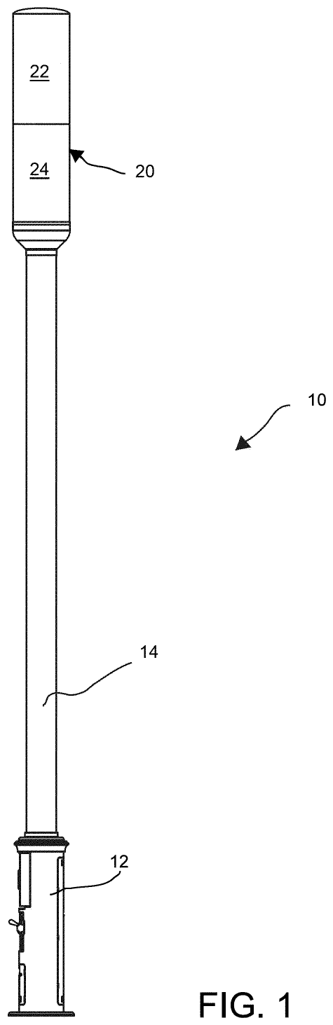

FIG. 1 illustrates one embodiment of a small cell pole 10 that may be utilized to support one or more antenna housings as discussed herein. Various features of this small cell pole are disclosed in co-owned U.S. Patent Publication No. 2017/0279187, the entire contents of which are incorporated herein by reference. As shown, the cell pole includes a lower equipment housing 12 that includes an inner cavity (e.g., interior) configured to house, for example, cell control equipment. The equipment housing 12 has a lower flange used to mount the housing to a surface (e.g., ground). Other installation methods are possible. Access panels and/or doors may be mounted to the equipment housing 12 to enclose equipment from the elements, while providing selective access, when desired, to modify, regulate, change out, or otherwise access the equipment within the housing 12. The housing may include locks, hinges, access doors, vents for passive radiant cooling, and/or viewing ports. Cable ports and other features may be formed therein during manufacture. Fasteners, such as threaded posts or bolts, may be formed on an upper surface (e.g., flange; not shown) of the equipment housing 12 to facilitate attachment of a pole 14 (e.g., monopole), which may support an antenna housing assembly 20. As set forth in U.S. Patent Publication No. 2017/0279187, the interior of the equipment housing 12 may open into the hollow interior of the pole 14. This allows passage of cables from the equipment housing(s) into the center of the pole for routing to, for example, one or more antennas and/or lights (not shown). Though illustrated as including the lower equipment housing 12, it will be appreciated that not all embodiments of the cell pole 10 require such a lower equipment housing. Along these lines, the lower end of the pole 14 may be configured for attachment to a ground surface and/or a subterranean equipment vault.

To better utilize a location of a wireless access point, it is becoming increasingly common for a dedicated cell pole or an existing utility pole (e.g., streetlight, stoplight etc.) to support two or more sets of antennas/radios, which may be disposed in vertically stacked antenna housings. In such an arrangement, wireless transceivers of two or more separate wireless providers and/or distinct types of wireless transceivers may be supported by a single pole (e.g., access location/point). As illustrated in FIG. 1, the antenna housing assembly 20 is formed of an upper antenna housing 22 and a lower antenna housing 24, which are vertically stacked. As illustrated, an upper end of the pole 14 connects to and supports the lower end of the lower antenna housing 24. An upper end of the lower antenna housing 24 connects to and supports the lower end of the upper antenna housing 24, which likewise could support an additional antenna housing (not shown). Though illustrated as having two antenna housings, it will be appreciated that the pole may support fewer antenna housings or more antenna housings. The use of the individual antenna housings allows the cell pole 10 to be a modular system that allows for adding additional antenna housings/sections as desired. For instance, different wireless providers may utilize different antenna housings and/or different antenna housing may provide antenna coverage for different azimuth directions.

Previous generations of antennas (e.g., 4G radios) often had operational powers of around 150 watts. When an individual antenna housing held three such radios, the total power of the enclosed radios would be 450 watts. A thermal load of the enclosed radios could typically be managed by providing vents at or near the bottom of the housing and at or near the top of the housing. Such vents permitted removal of heat from the housing via natural or forced convention. However, it has been found that newer antennas (e.g., 5G transceivers/radios) having higher operational power (e.g., 400-500 watts) tend to produce more heat than can be removed utilizing such simplified venting. For example, an antenna housing supporting three radios would be subject to an operation power of 1200-1500 watts. When three such radios are enclosed within a housing/shrouding, heat generated during operation tends to build up. This is further complicated in applications where antenna housings are vertically stacked. For instance, heat from a lower housing 24 tends to move upward into an upper housing 20, further increasing the temperature within the upper housing. Accordingly, it is desirable to more effectively vent heat generated by each antenna from the antenna housing. The present disclosure is broadly directed to wireless antenna housings or antenna support assemblies that effectively remove heat from the interior of the antenna housing/assembly to maintain desired operating temperatures.

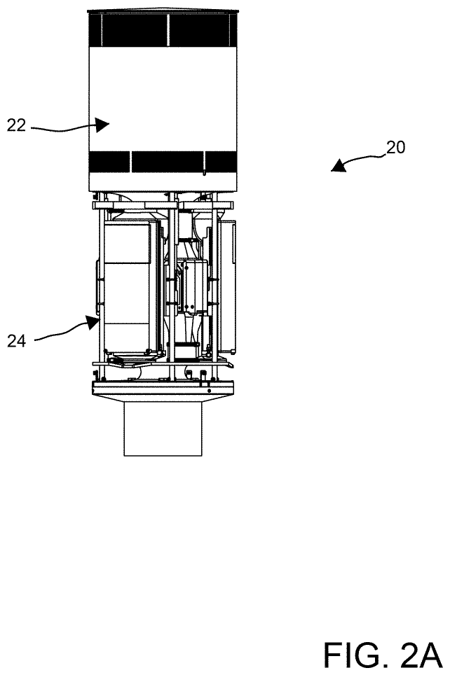

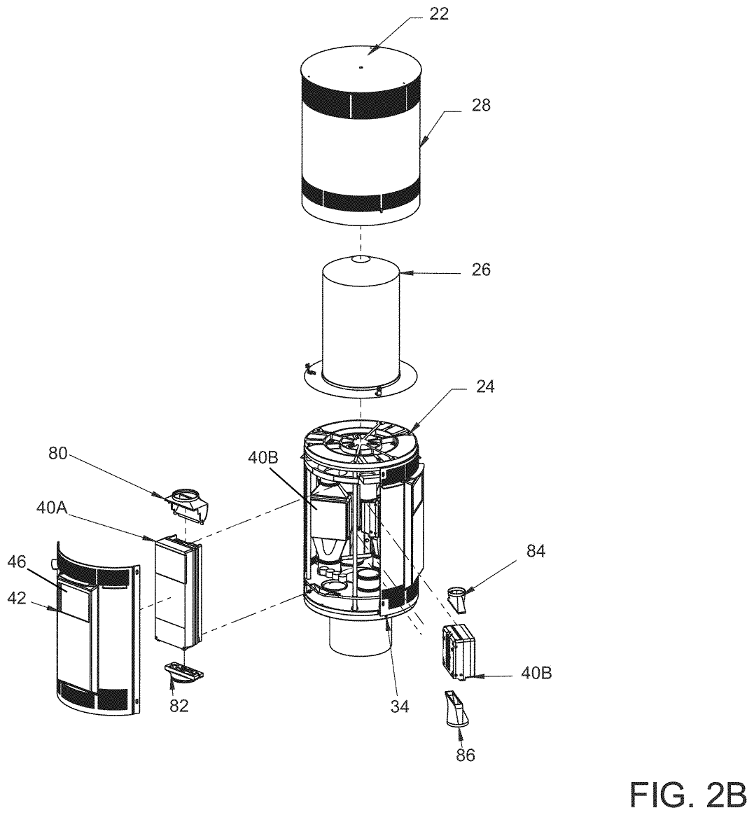

FIGS. 2A and 2B illustrate an embodiment of an antenna assembly 20 having the upper antenna housing 22 and the lower antenna housing 24. More specifically, FIG. 2A illustrates a side view of the antenna assembly 20 with a sidewall/shrouding removed from the lower antenna housing 24 and FIG. 2B illustrates a perspective exploded view of the antenna assembly 20. As illustrated, the upper antenna housing 22 includes an omnidirectional 4G wireless antenna 26 covered by a generally cylindrical shroud 28. The lower antenna housing 24 includes a plurality of fifth generation (e.g., 5G) wireless transceivers or radios 40A and a plurality of fourth generation (e.g., 4G) radios 40B (e.g., connected to the 4G antenna 26) disposed within its interior. Specifically, the lower antenna housing houses three 5G radios 40A and three 4G radios 40B. The 5G radios 40A and 4G radios 40B are referred to herein as radios 40 unless specifically referenced. During operation, the radios 40 collectively generate a significant heat load. The lower antenna housing 24 includes various features that improve airflow through the housing 24 improving overall heat rejection and thereby improving antenna performance.

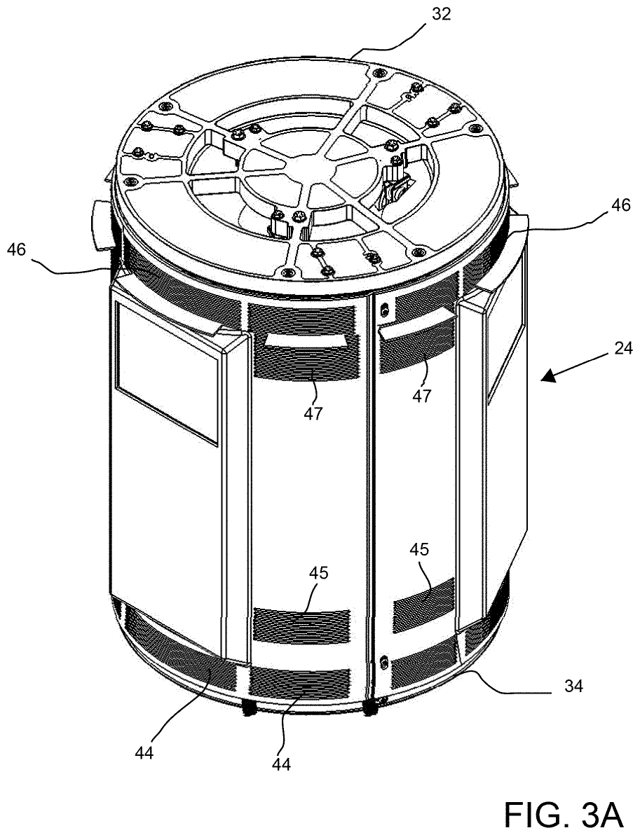

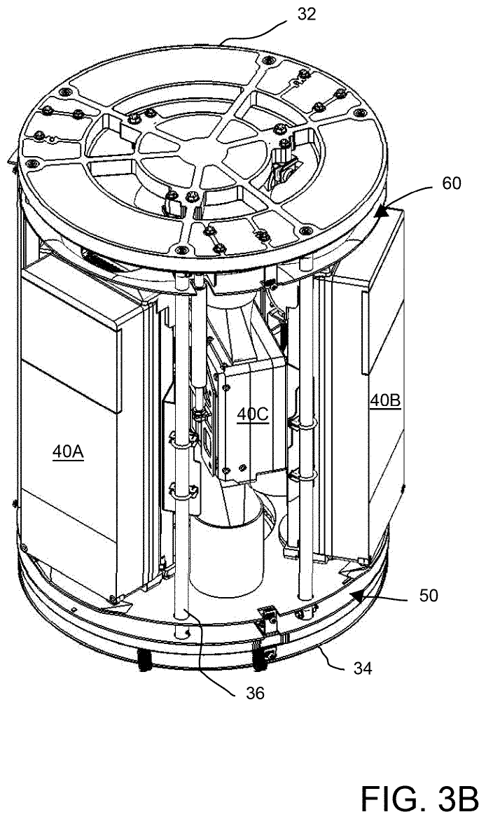

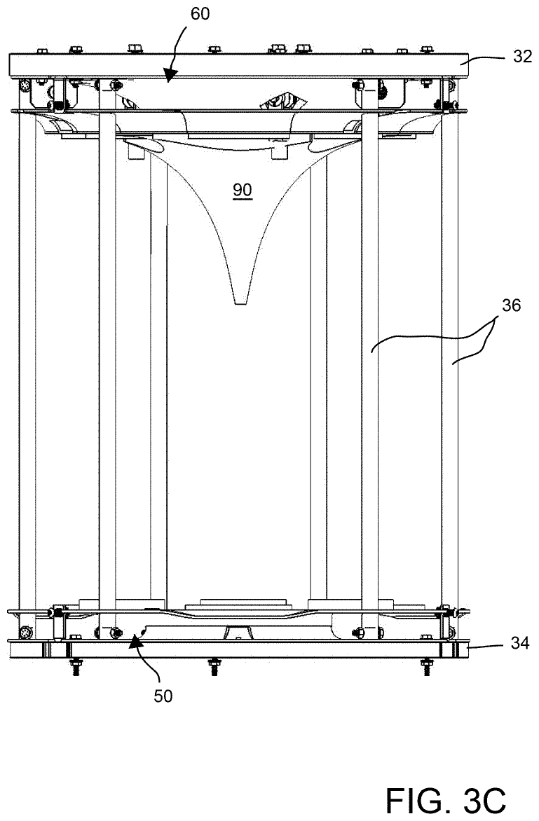

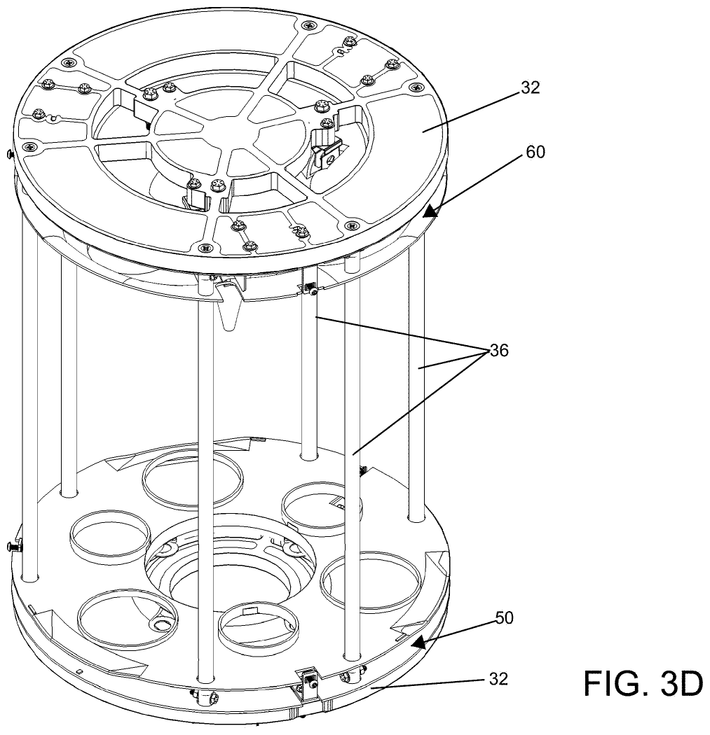

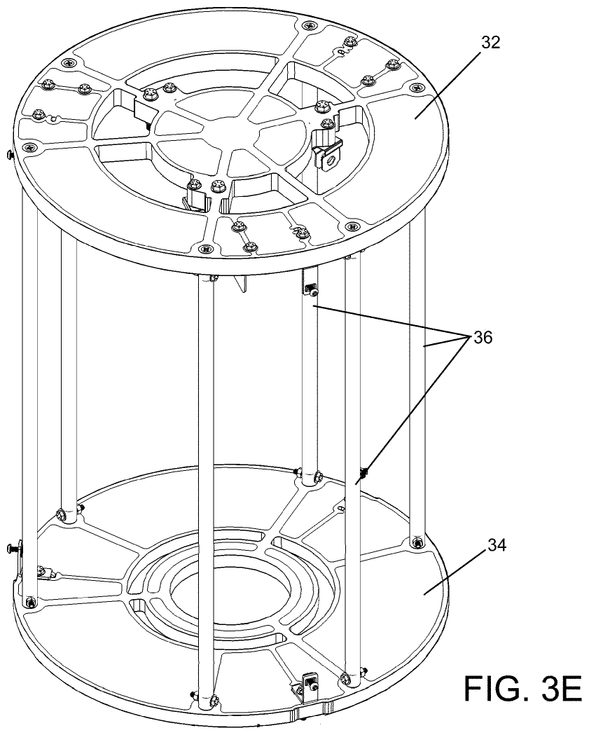

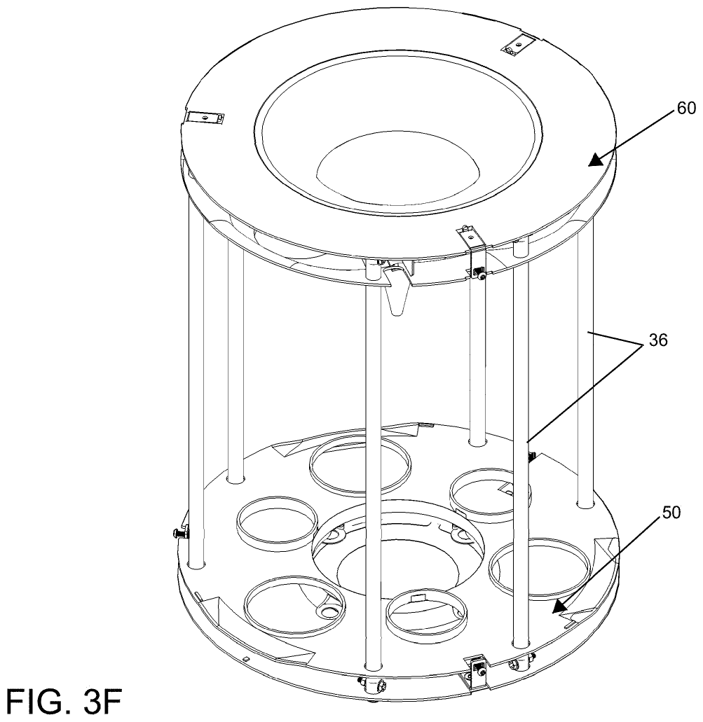

FIGS. 3A-3E variously illustrate the lower housing 24. Specifically, FIG. 3A illustrates a perspective view with various shrouds 42 enclosing an interior area of the housing, FIG. 3B illustrates the housing with the shrouds removed to show the various radios 40 disposed within the interior of the housing and FIGS. 3C and 3D illustrate side and perspective views, respectively, of the housing with the shrouds 42 and radios 40 removed to illustrate various internal structures of the housing 24. Figure, 3E further removes the manifolds. The antenna housing 24 includes an upper end and a lower end. In the illustrated embodiment, an upper plate 32 and a lower plate 34 form the upper and lower ends of the housing. In an embodiment, the plates 32, 34 are circular/annular, however this is not a requirement. The two plates 32, 34 each include multiple apertures, which permit the extension of wiring or cabling (not shown) through the antenna housing 24, when the housing 24 is attached to, for example, a pole and/or adjacent housings. In the illustrated embodiment, the two plates 32, 34 are disposed in a spaced relationship to define an interior volume there between. This interior volume is sized to house the plurality of radios 40 therein.

In the illustrated embodiment, a plurality of structural supports or struts 36 extend between the upper plate 32 and lower plate 34. The ends of the struts 36 are fixedly attached (e.g., welded, bolted, etc.) to each plate. As will be appreciated, when utilized in an assembled cell pole, the antenna housing 24 may become a structural member that supports structures attached to its upper end such as, for example, upper antenna housings, lights etc. Thus, the antenna housing may be required to support loads such as compressive loads and/or moment loads (e.g., wind loading) applied by supported structures or elements. Accordingly, the struts 36 may include various bracing with the plates to provide adequate structural rigidity. Further, when a single pole includes multiple antenna housings, the configuration of adjacent antenna housings may be different. For instance, a lower housing may have thicker plates and/or struts (e.g., to support greater loads) while upper antenna housings may have thinner plates and/or struts and/or be made of dissimilar materials.

In the illustrated embodiment, the struts 36 also form radio mounts, though separate mounts are possible and considered within the scope of the present disclosure.

The radios 40 supported by the antenna housing 24 may each have brackets that are configured to attach to at least one of the struts (e.g., span between two adjacent struts). In the illustrated embodiment, the antenna housing 24 supports three 5G radios 40A each of which has an active surface that faces outward from the housing to provide 360-degree coverage (e.g., three 120-degree sectors). Disposed between each of the 5G radios 40A is a 4G radio 40B.

Once the radios 40 are disposed within the antenna housing 24, the radios 40 may be at least partially enclosed within the interior of the housing 24 by or more shrouds 42 that each extend around a portion of the periphery of the housing and between the upper and lower plates. In an embodiment, the shroud(s) 42 at least partially define a sidewall of the antenna housing between its upper end and its lower end. Though utilizing the term ‘shroud,’ it will be appreciated that any component that at least partially encloses the radios within an interior of the housing between its upper and lower ends may be utilized. In any embodiment, it may be desirable to at least partially conceal the radios to provide a finished look and to allow a resulting wireless access point to better blend in with its surroundings. If the shroud(s) covers an active surface of the radios, the covering portion of the shroud is typically made of a material that is substantially transparent (e.g., transmission of greater than 90%) to radiofrequency (RF) waves. Such RF transparent materials include, without limitation, fiber glasses, polymers and/or fabrics. In other arrangements, the shroud(s) 42 may have an antenna aperture 46 that exposes an active or emitter surface of the radios 40 (e.g., 5G radios 40A).

To provide enhanced cooling for the antenna housing 24, the illustrated embodiment utilizes closed air flow paths that individually cool (e.g., pass over and/or through) each of the radios 40. That is, each radio is disposed in an air flow path (e.g., at least partially sealed air flow path) that enters the housing, passes over or through the radio (e.g., over a heat rejection surface of the radio) and is exhausted out of the housing. In the illustrated embodiment, this requires six separate air flow paths through the interior of the housing to individually cool the six radios 40 disposed within the housing. To provide multiple air flow paths into and out of the housing, the presented housing assembly utilizes a lower plenum 50 (e.g., intake manifold) disposed proximate to the lower end of the housing and an upper plenum 60 (e.g., exhaust manifold) disposed proximate to the upper end of the housing. See FIGS. 3A and 3B. The operation of these manifolds is further discussed below.

FIG. 3F illustrates another embodiment of an internal structure of the antenna housing. In this embodiment, rather than utilizing upper and lower end plates, the upper manifold 60 and lower manifold 50 form the upper and lower ends of the antenna housing. In such an arrangement, the strut 36 may extend between and connect to the manifolds 50, 60.

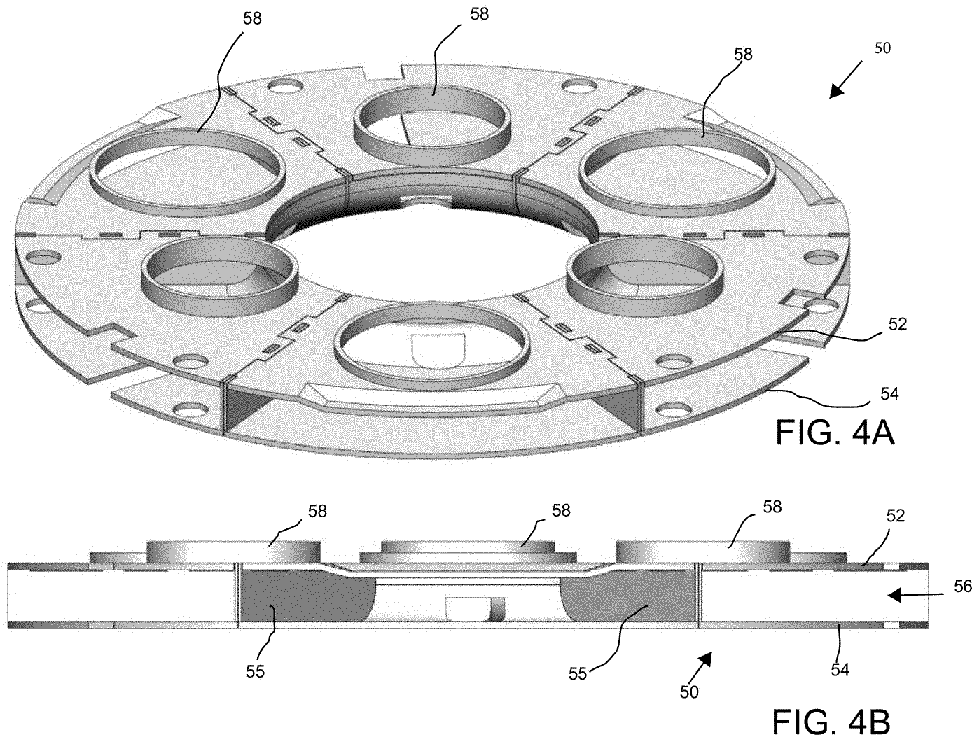

FIGS. 4A and 4B illustrate the lower plenum 50. In the illustrated embodiment, the lower plenum 50 is an annular plenum having an open interior. That is, the lower plenum 50 is a closed geometric shape/volume (e.g., similar to a toroid) having a central opening. The central opening allows for various cabling to pass through the center of the plenum 50 when incorporated into the antenna housing 24. The lower plenum 50 has an interior volume (e.g., generally hollow interior) formed between an upper surface 52 and a lower surface 54. In the illustrated embodiment, inner peripheral edges of the upper surface 52 and lower surface 54 connect to form a closed inner periphery of the plenum 50. The outer peripheral edges of these surfaces 52, 54 are spaced from one another forming an open outer periphery of the plenum 50. The open outer periphery forms an opening 56 into the interior volume of the plenum 50. When the lower plenum 50 is used to draw air into the housing 24, the opening 56 forms an inlet opening or inlet vent into the interior volume of the plenum 50 where ambient air may pass into the housing 24. To draw air into the housing, the lower plenum opening 56 draws air through openings 44 (e.g., vent slits) formed in a sidewall (e.g., shroud(s) 42) of the housing 24. See FIG. 3A. In various embodiments, a gasket may be disposed between the periphery of the opening 56 and the inside surface of the housing. However, this is not a requirement. In addition, a plurality of duct openings 58 are formed through the upper surface 52 of the plenum 50. These duct openings 56 provide airflow pathways between the interior volume of the lower plenum 50 and the interior of the housing 24. The plenum 50 may optionally include a plurality of dividers 55 within the interior volume that extend (e.g., radially) from the inner peripheral edge to the outer peripheral edge (e.g., to the opening). These dividers 55 may allow each duct opening 58 to open to a separate interior volume of the plenum 50 as well as a separate portion of the inlet opening 56.

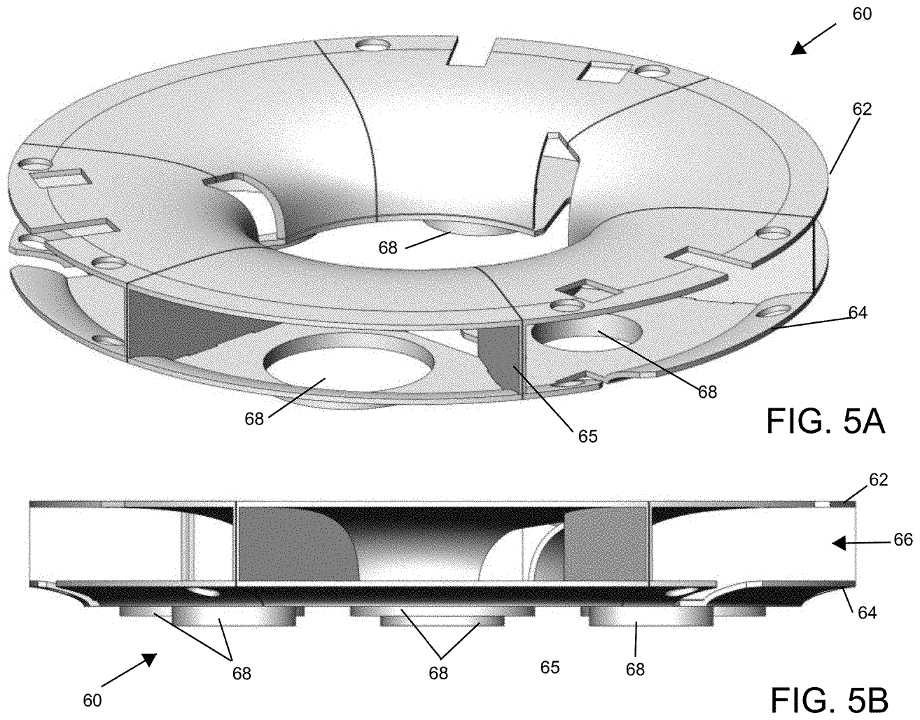

The upper plenum is illustrated in FIGS. 5A and 5B. Similar to the lower plenum 50, the upper plenum 60 is an annular plenum having a central opening that allows for various cabling to pass through the upper plenum 60 when incorporated into the antenna housing 24. The upper plenum 60 likewise has an interior volume (e.g., hollow interior) formed between an upper surface 62 and a lower surface 64. In the illustrated embodiment, inner peripheral edges of the upper surface 62 and lower surface 63 connect to form a closed inner periphery of the plenum 60 while the outer peripheral edges of these surfaces 62, 64 are spaced forming an open outer periphery of the plenum 60. The open outer periphery forms an outlet opening 66 exiting from the interior volume of the plenum 60. When the upper plenum 60 exhausts air from the housing 24, the opening 66 defines an exhaust vent for exhausting heated air out of the housing 24. To allow exhausting air from the housing, the opening 66 is disposed against openings 46 (e.g., vent slits) formed in a sidewall of the housing 24. The lower surface 64 of the plenum 66 includes a plurality of duct opening 68. These duct openings 68 provide airflow pathways between the interior volume of the lower plenum and the interior of the housing. The plenum 60 may optionally include a plurality of dividers 65 within the interior volume that extend (e.g., radially) from the inner peripheral edge to the outer peripheral edge (e.g., to the opening). These dividers 65 may allow each duct opening 68 to open to a separate interior volume of the plenum 60 as well as a separate portion of the outlet opening 66.

Each duct opening 58 in the lower plenum 50 may be connected (e.g., via ducting) to a corresponding duct opening 68 in the upper plenum 60 to form a closed air flow path through the interior of the housing 24. In an embodiment, each radio 40 within the interior of the housing may be at least partially disposed in a closed air flow path to allow for individually cooling each radio.

The plenums 50, 60 may be made of any appropriate material. In an embodiment, the plenums are metallic. In such an embodiment. The plenums may form structural members, for instance, where the plenums form the upper and lower ends of the antenna housing as discussed in relation to FIG. 3F. In another embodiment, the plenums are polymeric. In such an embodiment, the plenums may be formed in an injection molding process.

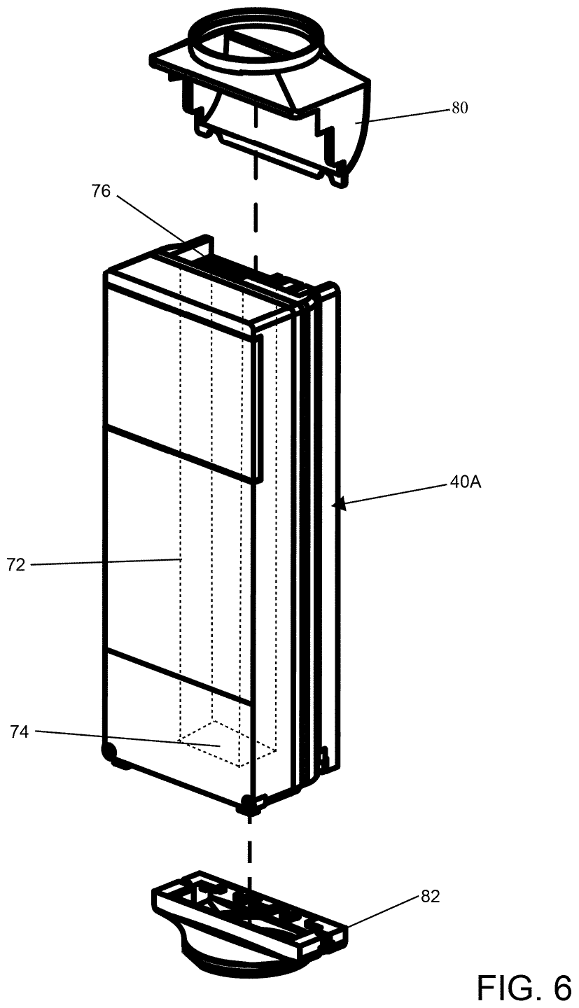

FIG. 6 illustrates one embodiment of a 5G radio 40A that may be disposed within an interior of the housing. In the illustrated embodiment, the 5G radio 40A is a Streetmacro 6701 antenna produced by Ericsson. It will be appreciated that the antenna housing disclosed herein may be utilized with a variety of antennas and that this antenna is presented by way of example only. Nonetheless, the Streetmacro antenna unit is representative of a general form of some 5G antenna units currently being installed. As illustrated, the radio 40A includes a rectangular prism-shaped housing having a front panel or radome 70, which is a thin-walled RF transparent area that protects the forward emitting surface of an RF antenna (not shown). The housing of the radio includes an internal cooling duct 72 that passes through the rearward portion of the housing from an inlet 74 in the bottom surface to an outlet 76 in the top surface. The cooling duct 72 passes over a heat rejection surface disposed within the interior of the radio 40A. The heat rejection surface may be a finned surface (e.g., aluminum) attached to a rearward surface of the RF antenna. Commonly, the radio will include a fan (not shown) to move air through the cooling duct 72 from the inlet 74 to the outlet 76. The air passing through the duct 72 passes over a heat rejection surface thereby cooling the antenna.

In the present embodiment, a lower end of an upper connecting duct 80 connects to an upper surface of the radio 40A around the outlet 76. An upper end of the upper connecting duct 80 is configured to engage one of the duct openings 68 in the upper plenum 60. Likewise, an upper end of a lower connecting duct 82 connects to a lower surface of the radio 40A around the inlet 74. A lower end of the lower connecting duct 82 is configured to engage one of the duct openings 58 in the lower plenum 58. Similar ducts for use in connecting a wireless radio to inlet and outlet vents are set forth in co-owned U.S. Pat. No. 11,201,382, filed on Apr. 1, 2020, the entire contents of which is incorporated herein by reference. The connecting ducts, 80, 82, in conjunction with the upper and lower plenums 50, 60, allow the radio 40A to draw air from outside of the housing 24 through the cooling duct 72 (i.e., over a heat rejecting surface(s) of the RF antenna) and expel the air out of the housing 24. Such air may pass through the housing 24 without intermingling with air in the interior of the housing. In the absence of such a closed air flow path, air would be drawn into the internal cooling duct 72 of the radio from the interior of the housing and expelled back into the interior of the antenna housing 24. This would result in inefficient cooling of the antenna and increased temperatures within the antenna housing.

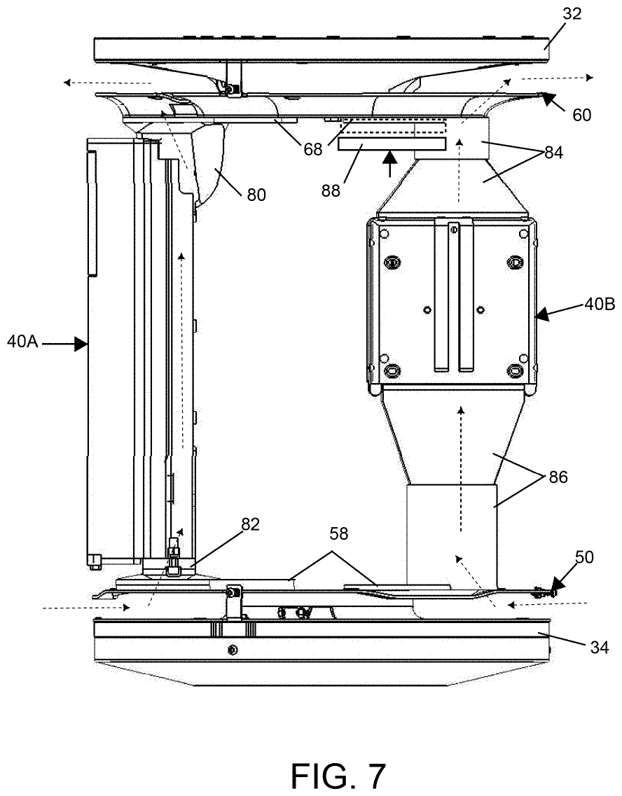

The connection of the 5G radio 40A between the upper plenum 60 and the lower plenum 50 is best illustrated in FIG. 7. As illustrated, the 4G radio 40B may likewise be connected between the plenums 50, 60 utilizing appropriate connecting ducts 84, 86, which may be configured for a specific radio. As discussed herein, the radios have internal cooling ducts that pass through the interiors of the radios. However, not all wireless radios include an internal cooling duct. In such instances, the upper and lower connecting ducts may connect to a plenum that receives, for example, a rearward surface (e.g., heat rejecting surface) of a radio. Such a plenum is set forth in U.S. Pat. No. 11,201,382 as incorporated above.

As illustrated, the ducts 80, 82 attached to the radio 40A engage with one of the upper plenum duct openings and one of the lower plenum duct openings. Once connected between the lower and upper plenums, a fluid flow path is established across or through the radio. More specifically, air is down into the inlet of the lower plenum 50 into the interior of the lower plenum, passes through one of the duct openings 58 and into the inlet duct 82, through or across the radio 40A, through the outlet duct 80, into the interior of the upper plenum and out the exhaust port. In short, a flow path is established where air is drawn from outside the antenna housing, cools the radio and is exhausted back outside the housing. Each individual air flow path may include a fan, which may be integrated into the radio or disposed anywhere within the flow path (not shown). In such an embodiment, each individual flow path may be an active air flow path wherein air is forced through the flow path for cooling. As further illustrated in FIG. 7, a cap 88 may be placed over one or more of the duct openings 68 or 58 (not shown). That is, unused ducts in the manifolds may be capped.

While the individual flow paths provide significant benefits for cooling the individual radios, heat may still build up within the interior of the housing 24 (e.g., behind the radios). Accordingly, additional features are provided to facilitate the removal of heated air from an interior of the housing as well as to partially isolate the housing from an adjacent antenna housing, if present. To provide cooling for the interior of the housing 24 the housing includes various vents 45, 47 that open into the interior of the housing (i.e., bypassing the plenums). See FIG. 3A. As illustrated, the vents 45, 47 are formed as a plurality of elongated apertures extending through various surfaces of the antenna housing (e.g., through one or more shrouds 42). Variation is possible. What is important is that the housing has various vent openings, which in the present disclosure provide air flow into and out the interior of the housing 24. As illustrated, a first set of vents 45 are disposed through the housing sidewall above the vents 44 that are juxtaposed with the lower plenum. The first set of vents 45 (e.g., lower vents) allow cool air to enter the interior of the housing. The second set of vents 47 (e.g., upper vents) are disposed through the housing sidewall below the vents 46 that are juxtaposed with the upper plenum 60. The second set of vents allow air warmed within the interior of the housing 24 to exit from the interior of the housing. In an embodiment, these vents may allow for natural convective air flow. In another embodiment, a fan may (not shown) facilitate circulation of air through these vents.

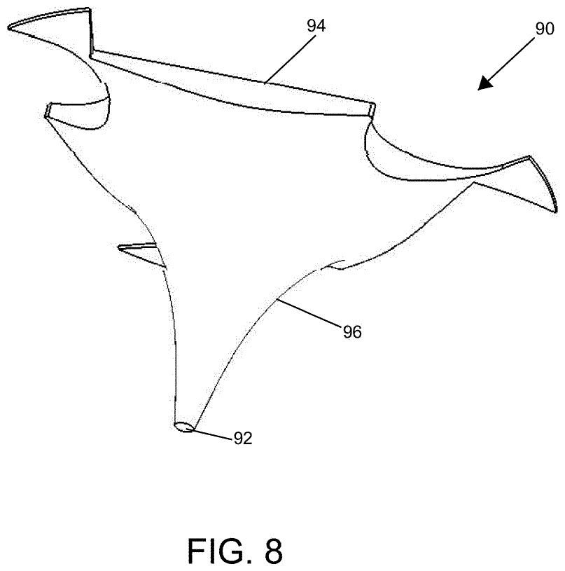

One difficulty in moving air through the interior of the housing is the lack of space and blockage caused by the plurality of radios disposed therein. Though air is heated in the interior of the housing by the radios (even if actively cooled by the individual flow paths), the heated air tends to stagnate within the housing, especially when utilizing natural convective air movement. The present inventors have recognized that if the warmed air moves directly upward as it is heated within the interior of the housing, the heated air lacks an outward vector of movement that facilitates movement of the heated air out of the upper vents 47. While the heated/warm air does move through the upper vents, the heated air tends to stagnate in the upper portion of a housing. To increase the rate of air passing through the upper vents, the inventors have incorporated a three-dimensional deflector 90 that is disposed within the interior of the housing 24. See FIGS. 3C, 8 and 9.

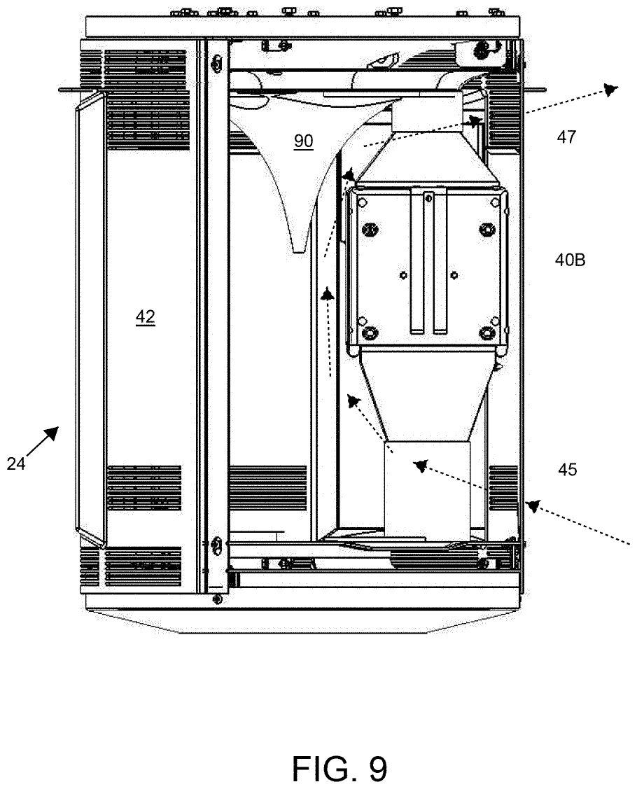

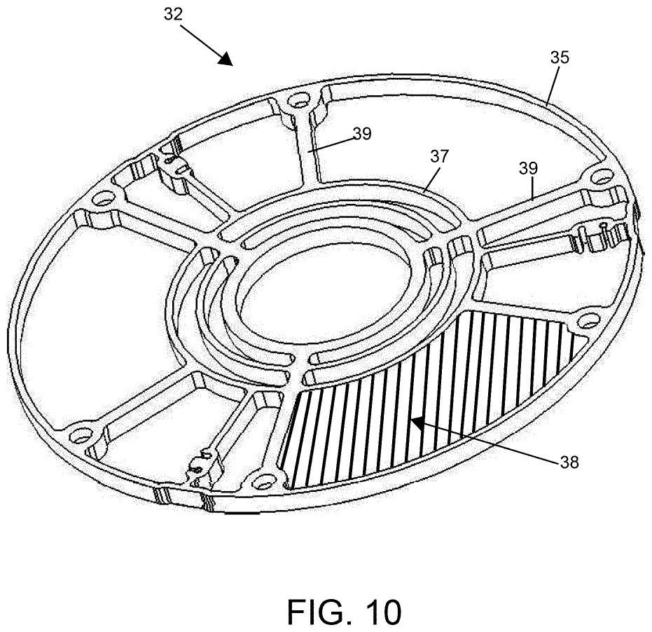

The deflector typically is disposed near the center of the housing and extends over a portion of the length of the housing. As illustrated. The deflector 90 expands from a smaller cross-dimension at its downward end/tip 92 (e.g., positioned toward the lower end of the housing) and a larger cross-dimension at its upper end/base 94, which is typically connected proximate to the upper plenum 60. The surface of the deflector 90 is a sloped surface 96 (e.g., generally arcuate) along any line between the tip 92 and the base 94. Stated otherwise, the three-dimension shape of the deflector is generally conical. However, it will be appreciated that the three-dimensional shape may be irregular. Such an irregular shape may be required to fit between the radios and ducting within the interior of the housing. What is important is that the deflector expands in cross dimension between its lower end and its upper end. As best illustrated by the dashed arrows in FIG. 9, when air enters the housing 24 through the lover vents 45, the air moves upward as it warms. As the air moves upward, a portion of the warmed air contacts the arcuate surface of the deflector. This air is deflected/pushed outward. That is, an outward vector of movement is imparted into the rising air. This outward movement of the warmed air helps push air out of the upper vents 47. As a result, the rate of air movement through the upper vents is significantly increased (e.g., at least doubled).

As noted above, the housing 24 may support additional housings. For instance, two housings may include a plurality of radios (e.g., 5G radios and 4G radios). The 4G radios in both such housings may connect to a common 4G antenna supported by the two radio housings. In such an arrangement, it is desirable to reduce the heat transferred by any lower housing to a housing supported above that housing. FIG. 10 illustrates one of the end plates 32 or 34 (hereafter 32) of the housing. As illustrated, the end plate 32 is an annular plate having an open interior to allow for cabling to pass through the housing. Additionally, the end plate includes an outer rim 35 an inner rim 37 and a plurality of spokes 37 extending between the rims 35, 37. The plate resembles a spoke and hub wheel. The spaces between the rims 35, 37 and any two adjacent spokes reduce the overall weight of the housing. Additionally, these spaces provide access points to housings above/below the housing, if needed. However, when these spaces are not needed for access, it has been found that insulating the space significantly reduces the thermal transfer between adjacent housings. Along these lines, each space may be filled with an insulative material 38 such as, without limitation, an open or closed cell foam. Additionally, thin annular discs may be attached to the upper and lower surfaces of the plate 32.

As set forth above, the antenna housing 24 allows for housing multiple radios, which may be differently configured (e.g., 5G radios and 4G radios), while providing each radio with an individual air flow paths as well as providing additional features for cooling and/or thermally isolating the housing. The ability to combine 5G radios and 4G radios within a common housing, while allowing the 4G radios to utilize a common antenna supported by the housing is considered novel in and of itself. That is, aspects of the combined housing are considered novel with or without the individual cooling ducts and/or manifolds.

The foregoing description has been presented for purposes of illustration and description. Furthermore, the description is not intended to limit the inventions and/or aspects of the inventions to the forms disclosed herein. Consequently, variations and modifications commensurate with the above teachings, and skill and knowledge of the relevant art, are within the scope of the presented inventions. The embodiments described hereinabove are further intended to explain best modes known of practicing the inventions and to enable others skilled in the art to utilize the inventions in such, or other embodiments and with various modifications required by the particular application(s) or use(s) of the presented inventions. The appended claims shall be construed to include alternative embodiments to the extent permitted by the prior art.

What is claimed is:

1. An antenna support assembly configured for attachment to a pole, comprising:
a housing having an upper end, a lower end spaced from the upper end, and at least one sidewall surface extending between the upper end the lower end, wherein the upper end, the lower end and the sidewall surface at least partially define an enclosed interior area of the housing;
upper and lower manifolds disposed within the housing proximate to the upper end and lower end, respectively, each of the upper manifold and the lower manifold having:
an interior volume having a vent port that opens from the interior volume through the sidewall surface of the housing, and
at least first and second duct openings that open from the interior volume of the manifold into the interior area of the housing;
a first set of ducting connecting a first duct opening of the upper manifold and a first duct opening of the lower manifold to define a first flow path between the lower manifold and the upper manifold through the interior of the housing; and
a second set of ducting connecting a second duct opening of the upper manifold and a second duct opening of the lower manifold to define a second flow path between the lower manifold and the upper manifold through the interior area of the housing.

2. The antenna support assembly of claim 1, further comprising:
a first radio at least partially disposed in the first set of ducting; and
a second radio at least partially disposed in the second set of ducting.

3. The antenna support assembly of claim 2, wherein at least one of the first radio and the second radio comprises:
an integrally formed cooling duct extending through the radio between an inlet and an outlet, wherein the cooling duct of the radio fluidly connects to ducting extending between the lower manifold and the upper manifold.

4. The antenna support assembly of claim 1, wherein the upper and lower manifolds each include at least three duct openings that open into the interior of the housing.

5. The antenna support assembly of claim 3, wherein the upper and lower manifolds each include at least six duct openings that open into the interior of the housing.

6. The antenna support assembly of claim 1, wherein the interior volume of each manifold is separated into a first internal volume in fluid communication with the first duct opening and a second internal volume in fluid communication with the second duct opening.

7. The antenna support assembly of claim 1, wherein at least one of the upper and lower manifolds is an annular manifold, wherein the interior volume surrounds a central opening of the annular manifold.

8. The antenna support assembly of claim 7, wherein the vent port is formed about at least a portion of an outer periphery of the annular manifold.

9. The antenna support assembly of claim 8, wherein the vent port extends about the entire outer periphery of the annular manifold.

10. The antenna support assembly of claim 9, further comprising:
at least first and second dividers disposed within the interior volume and extending from the outer periphery to an inner periphery of the annular manifold, wherein the dividers divide the interior volume into at least first and second interior volumes.

11. The antenna support assembly of claim 1, further comprising:
an air deflector disposed within the interior area of the housing, the air deflector having a body with closed exterior surface expanding from a smaller cross dimension to a larger cross dimension over a portion of a length of the housing between the lower end and the upper end, wherein the larger cross-dimension is disposed proximate to the upper end of the housing.

12. The antenna support assembly of claim 1, wherein the upper plenum forms the upper end of the housing, and the lower plenum forms the lower end of the housing.

13. The antennas support assembly of claim 12, further comprising at least one strut extending between the upper plenum and the lower plenum.

14. The antenna support assembly of claim 1, further comprising:
an upper end plate forming the upper end of the housing; and
a lower end plate forming the lower end of the housing, wherein the upper manifold is disposed proximate to the upper end plate and the lower manifold is disposed proximate to the lower end plate.

15. The antenna support assembly of claim 1, wherein the upper manifold and lower manifold are injection molded.

16. An antenna assembly, comprising:
an elongated housing having an upper end, a lower end and a sidewall surface extending between the upper end the lower end, wherein the upper end, the lower end and the sidewall define an interior area of the housing;
an upper manifold having an exhaust port venting through the sidewall surface, wherein the upper manifold is disposed proximate to the upper end;
a lower manifold having an inlet port venting through the sidewall surface, wherein the lower manifold is disposed proximate to the lower end;
at least two radios disposed between the upper manifold and the lower manifold;
ducting connecting each radio to an interior of the lower manifold and an interior of the upper manifold.

17. The antenna assembly of claim 16, wherein the at least two radios comprise a first radio and a second radio, wherein the first and second radios are differently configured.

18. The antenna assembly of claim 17, wherein the first radio is a 5G radio and the second radio is a 4G radio.

19. The antenna assembly of claim 17, wherein each radio is connected to an inlet duct that draws air from the lower manifold and an outlet duct that expels air to the upper manifold.

20. The antenna assembly of claim 19, wherein at least one of the radios has an internal fluid flow path extending through the radio between an inlet and an outlet.
